(19) United States
(12) Patent Application Publication
(10) Pub. No.: US 2026/0227350 A1
(43) Pub. Date: Aug. 6, 2026

(54) DIVERSIFYING SEM MEASUREMENT SCHEME FOR IMPROVED ACCURACY

(71) Applicant: ASML Netherlands B.V., Veldhoven (NL)

(72) Inventors: Alexandru ONOSE, Eindhoven (NL); Tiago BOTARI, Veldhoven (NL); Anagnostis TSIATMAS, San Jose, CA (US); Markus Gerardus Martinus Maria VAN KRAAIJ, Eindhoven (NL)

(73) Assignee: ASML Netherlands B.V., Veldhoven (NL)

(21) Appl. No.: 19/153,999

(22) PCT Filed: Jan. 8, 2024
(86) PCT No.: PCT/EP2024/050307

§ 371 Date: Aug. 6, 2025

Related U.S. Application Data
(60) Provisional application No. 63/443,832, filed on Feb. 7, 2023.
(60) Provisional application No. 63/452,342, filed on Mar. 15, 2023.

(51) Int. Cl. G01N 23/2251; G01N 23/2206

(52) U.S. Cl. CPC G01N 23/2251; G01N 23/2206; G01N 2223/071; G01N 2223/102; G01N 2223/401; G01N 2223/418

(57) ABSTRACT

A charged particle beam inspection method includes measuring a sample under multiple different signal acquisition modalities. Each modality may comprise a different set of inspection parameters that may be optimized for different purposes such as high resolution or high acquisition speed. Measurements from the different signal acquisition modalities may be combined to form a synthesized image using a deconvolution or other optimization task. The synthesized image may achieve superior resolution at higher throughput than is achievable with a single high-resolution or high-speed scan.

### CROSS-REFERENCE TO RELATED APPLICATIONS

This application claims priority to both U.S. application 63/443,832 which was filed on 7 Feb. 2023 and U.S. application 63/452,342 which was filed on 15 Mar. 2023 and which are incorporated herein in its entirety by reference.

### FIELD

The description herein relates to measurement schemes that may be useful in the field of charged particle beam systems, and more particularly, to systems and methods that may be applicable to charged particle inspection systems such as scanning electron microscope (SEM) tools.

### BACKGROUND

Inspection and metrology systems may be used for sensing physically observable phenomena. For example, charged particle beam tools, such as electron microscopes, may comprise detectors that receive charged particles projected from a sample and that output detection signals. Detection signals may be used to reconstruct images of sample structures under inspection and may be used, for example, to reveal defects in the sample. Accurate imaging and detection of defects in a sample is increasingly important in the manufacturing of semiconductor devices, which may include large numbers of densely packed, miniaturized integrated circuit (IC) components. Inspection systems may be provided for this purpose.

With continuing miniaturization of semiconductor devices, inspection systems continue to suffer a tradeoff between competing parameters, such as speed and accuracy. For example, some inspections may use low beam currents to achieve high resolution at the expense of low throughput and high signal-to-noise ratio (SNR). Some inspections may use higher beam currents, resulting in higher throughput and better SNR, at the expense of lower resolution.

### SUMMARY

Some embodiments of the present disclosure provide a charged particle beam inspection method. The charged particle beam inspection method may comprise: measuring a first region of a sample with a charged particle beam inspection apparatus under a first signal acquisition modality to obtain a first signal profile; measuring a second region of the sample with the charged particle beam inspection apparatus under a second signal acquisition modality to obtain a second signal profile, the second signal acquisition modality being different from the first signal acquisition modality in an inspection parameter of the charged particle beam apparatus; and generating, using an optimization task, an inspection image based on a synthesis of the first signal profile and the second signal profile.

Some embodiments may comprise a non-transitory computer-readable medium. The non-transitory computer-readable medium may store a set of instructions. The set of instructions may be executable by at least one processor of an apparatus to cause the apparatus to perform the method above.

Some embodiments of the present disclosure provide a charged particle beam apparatus. The charged particle beam apparatus may comprise: a charged particle beam source configured to generate a beam of primary charged particles; a charged particle optical system configured to direct the beam of primary charged particles at a sample surface to inspect the sample surface; a charged particle detector configured to detect charged particles returned from the sample surface; and a controller comprising one or more processors and configured to cause the charged particle beam apparatus to perform.

### BRIEF DESCRIPTION OF THE DRAWINGS

The above and other aspects of the present disclosure will become more apparent from the description of exemplary embodiments, taken in conjunction with the accompanying drawings.

FIG. 1 is a diagrammatic representation of an exemplary electron beam inspection (EBI) system, consistent with embodiments of the present disclosure.

FIGS. 2A-B are diagrams illustrating a charged particle beam apparatus that may be an example of an electron beam tool, consistent with embodiments of the present disclosure.

FIG. 3 is a diagrammatic representation of exemplary signal acquisition modalities, consistent with embodiments of the present disclosure.

FIG. 4 is a diagrammatic representation of an example measurement acquisition scheme, consistent with embodiments of the present disclosure.

FIGS. 5A-C are diagrammatic representations of example measurement acquisition schemes, consistent with embodiments of the present disclosure.

FIG. 6 is a diagrammatic representation of an example measurement acquisition scheme, consistent with embodiments of the present disclosure.

FIG. 7 a flowchart illustrating an example method that may be useful for producing a synthetic image from a plurality of signal acquisition modalities using an optimization task, consistent with embodiments of the disclosure.

FIG. 8 is a diagrammatic representation of an exemplary application of a method a method 700 that may be useful for producing a synthetic image from a plurality of signal acquisition modalities using an optimization task, consistent with embodiments of the disclosure.

FIG. 9 a flowchart illustrating an example method that may be useful for producing a synthetic image from a plurality of signal acquisition modalities, consistent with embodiments of the disclosure

### DETAILED DESCRIPTION

Reference will now be made in detail to exemplary embodiments, examples of which are illustrated in the drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses, systems, and methods consistent with aspects related to subject matter that may be recited in the appended claims. For example, although some embodiments are described in the context of utilizing charged-particle beams (e.g., electron beams), the disclosure is not so limited. Other types of charged particle beams (e.g., photon beams) may be similarly applied. Furthermore, other imaging systems may be used, such as optical imaging, photodetection, x-ray detection, or the like.

Electronic devices are constructed of circuits formed on a piece of silicon called a substrate. Many circuits may be formed together on the same piece of silicon and are called integrated circuits or ICs. With advancements in technology, the size of these circuits has decreased dramatically so that many more of them can fit on the substrate. For example, an IC chip in a smart phone can be as small as a fingernail and yet may include over 2 billion transistors, the size of each transistor being less than 1/1,000th the width of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SEM can be used to image these extremely small structures, in effect, taking a “picture” of the structures. The image can be used to determine if the structure was formed properly and also if it was formed in the proper location. If the structure is defective, then the process can be adjusted so the defect is less likely to recur. To enhance throughput (e.g., the number of samples processed per hour), it is desirable to conduct inspection as quickly as possible.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture,” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take in parallel multiple “pictures” of the wafer, which can be used separately or be stitched together to generate the inspection image. By using multiple electron beams, the SEM may provide more electron beams onto the structures for obtaining these multiple “pictures,” resulting in more electrons exiting from the structures. Accordingly, the detector may receive more exiting electrons simultaneously and generate inspection images of the structures of the wafer with higher efficiency and faster speed.

Typically, the detection process involves measuring the magnitude of an electrical signal generated when electrons land on the detector. In another approach, electron counting may be used, in which a detector may count individual electron arrival events as they occur. In either approach, intensity of the secondary beam may be determined based on electrical signals generated in the detector that vary in proportion to the change in intensity of the secondary beam.

Various inspection parameters can influence competing interests in an inspection process, such as speed and resolution. For example, the landing energy and incident angle of an electron beam may have a significant impact on the interaction volume of a sample (the region within which incident electrons interact with the material of the sample to generate, e.g., secondary and backscattered electrons). Beam current can influence, e.g., probe spot size and surface charging effects. These characteristics may be important factors in the scan speed and effective resolution of the inspection tool. For example, the size of the interaction volume may relate to the minimum pixel size of an image generated during the inspection process, and thus to the finest level of detail that is resolvable.

A high energy beam, for instance, may generate a large interaction volume. This may yield a large number of emitted electrons from the sample surface over a large area. The large number of electrons may be sufficient to achieve a high SNR and a faster acquisition of a larger sample pixel, resulting in faster scan speed. However, the large size of the interaction volume also limits the minimum achievable resolution of a resulting image. On the other hand, a small interaction volume may reverse these costs and benefits. Small interaction volumes may be achieved, e.g., using a low-energy or normal incidence beam to generate a finer resolution image. However, the lower yield of emitted electrons may be more difficult to distinguish from noise, resulting in smaller pixels and slower scan times that harm throughput. Conventional inspection systems therefore suffer an unavoidable tradeoff between speed and resolution.

Another tradeoff affecting the speed of an inspection process is the risk of damage to the features under inspection. High beam current inspection may not be suitable for all areas of a sample, especially those containing sensitive components. A low beam current setting may be chosen to avoid damage to such sensitive areas, but it may come at the expense of reducing the scan speed of the entire sample.

Embodiments of the present disclosure may provide an inspection apparatus and inspection method for producing high resolution inspection images with high throughput. The inspection apparatus may comprise, e.g., a charged particle beam apparatus such as a SEM tool or other electron beam tool. The apparatus may be configured to scan a region of a sample surface under a plurality of signal acquisition modalities. Each signal acquisition modality may comprise a different set of inspection settings or other inspection parameters to yield a different signal profile from the sample surface. Different signal acquisition modalities may be optimized for different purposes, such as to achieve, e.g., high acquisition speed or high resolution. Optimization may comprise using different inspection settings to achieve different interaction volumes or other inspection parameters.

The embodiments of the present disclosure may merge information obtained under the different signal acquisition modalities to generate high resolution inspection images. For example, using known information about the parameters of each respective signal acquisition modality, it is possible to merge the acquired images by performing image synthesis or deconvolution. This can be achieved by, e.g., solving an optimization task. Image synthesis/deconvolution may be used to combine images or features from different signal acquisition modalities, or to identify and remove system noise from the images. The embodiments of the present disclosure may allow the inference of charged particle inspection images with higher accuracy than what other systems could achieve at the same measurement speed, or a higher measurement speed than what other systems could achieve at the same resolution or accuracy.

In some embodiments, the inspection apparatus may scan an entire region of the sample under a first signal acquisition modality. The inspection apparatus may then scan the entire region of the sample under a second signal acquisition modality different from the first signal acquisition modality. The region may comprise, e.g., a single scan line or a full field of view of the inspection apparatus. By measuring the same location with multiple signal acquisition modalities, more information about the region may be obtained to yield a higher resolution image than would be available using a single signal acquisition modality.

In some embodiments, the inspection apparatus may switch between signal acquisition modalities during a scan of the region. For example, the inspection apparatus may vary inspection settings on a pixel-by-pixel basis. In some embodiments, the inspection apparatus may alternate between two or more signal acquisition modalities in a repeating sequence. In some embodiments, the inspection apparatus may alternate between two or more signal acquisition modalities in an irregular or non-repeating sequence. In some embodiments, the inspection apparatus may alternate between two or more signal acquisition modalities as determined or updated in a feedforward or feedback manner based on, e.g., real-time measurements or predetermined information, such as pattern data or prior scans of reference samples.

In some embodiments, pattern aware sampling may be used to determine the appropriate areas for switching between a first signal acquisition modality and a second signal acquisition modality. For example, an initial coarse scan or pattern design file may be used to identify transition areas in a circuit pattern or other inspection sample. A transition area may be, e.g., an edge of a circuit pattern feature at which a sharp change in wafer topography is present. Such an edge feature may require higher resolution imaging than what is needed at, e.g., relatively flat regions on either side of the edge feature. Thus, pattern aware sampling may be used to switch between a first signal acquisition modality that is suitable for flat features and a second signal acquisition modality that is optimized for edge features.

Objects and advantages of the disclosure may be realized by the elements and combinations as set forth in the embodiments discussed herein. However, embodiments of the present disclosure are not necessarily required to achieve such exemplary objects or advantages, and some embodiments may not achieve any of the stated objects or advantages.

Without limiting the scope of the present disclosure, some embodiments may be described in the context of providing detection systems and detection methods in systems utilizing electron beams (“e-beams”). However, the disclosure is not so limited. Other types of charged particle beams (such as proton beams) may be similarly applied. Furthermore, systems and methods for detection may be used in other imaging systems, such as optical imaging, photon detection, proton detection, x-ray detection, ion detection, or the like. Photon detection may comprise light in the infrared, visible, UV, DUV, EUV, x-ray, or any other wavelength range. Therefore, while detectors in the present disclosure may be disclosed with respect to electron detection, some embodiments of the present disclosure may be directed to detecting other charged particles or photons.

As used herein, unless specifically stated otherwise, the term “or” encompasses all possible combinations, except where infeasible. For example, if it is stated that a component includes A or B, then, unless specifically stated otherwise or infeasible, the component may include A, or B, or A and B. As a second example, if it is stated that a component includes A, B, or C, then, unless specifically stated otherwise or infeasible, the component may include A, or B, or C, or A and B, or A and C, or B and C, or A and B and C.

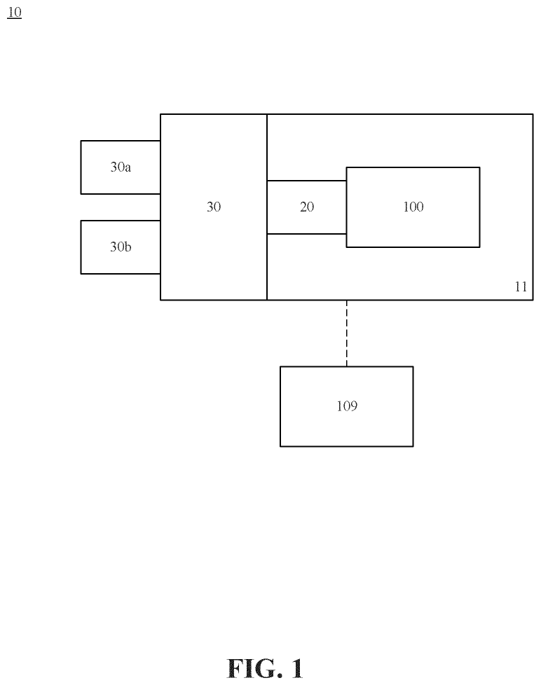

Reference is now made to FIG. 1, which illustrates an exemplary electron beam inspection (EBI) system 10 that may be used for wafer inspection, consistent with embodiments of the present disclosure. As shown in FIG. 1, EBI system 10 includes a main chamber 11 a load/lock chamber 20, an electron beam tool 100 (e.g., a scanning electron microscope (SEM)), and an equipment front end module (EFEM) 30. Electron beam tool 100 is located within main chamber 11 and may be used for imaging. EFEM 30 includes a first loading port 30a and a second loading port 30b. EFEM 30 may include additional loading ports. First loading port 30a and second loading port 30b receive wafer front opening unified pods (FOUPs) that contain wafers (e.g., semiconductor wafers or wafers made of other materials) or samples to be inspected (wafers and samples may be collectively referred to as “wafers” herein).

One or more robotic arms (not shown) in EFEM 30 may transport the wafers to load/lock chamber 20. Load/lock chamber 20 is connected to a load/lock vacuum pump system (not shown) which removes gas molecules in load/lock chamber 20 to reach a first pressure below the atmospheric pressure. After reaching the first pressure, one or more robotic arms (not shown) may transport the wafer from load/lock chamber 20 to main chamber 11. Main chamber 11 is connected to a main chamber vacuum pump system (not shown) which removes gas molecules in main chamber 11 to reach a second pressure below the first pressure. After reaching the second pressure, the wafer is subject to inspection by electron beam tool 100. Electron beam tool 100 may be a single-beam system or a multi-beam system. A controller 109 is electronically connected to electron beam tool 100, and may be electronically connected to other components as well. Controller 109 may be a computer configured to execute various controls of EBI system 10. While controller 109 is shown in FIG. 1 as being outside of the structure that includes main chamber 11, load/lock chamber 20, and EFEM 30, it is appreciated that controller 109 can be part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any other type of circuit capable of data processing. The processor may also be a virtual processor that includes one or more processors distributed across multiple machines or devices coupled via a network.

In some embodiments, controller 109 may further include one or more memories (not shown).

A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

A charged particle beam microscope, such as that formed by or which may be included in EBI system 10, may be capable of resolution down to, e.g., the nanometer scale, and may serve as a practical tool for inspecting IC components on wafers. With an e-beam system, electrons of a primary electron beam may be focused at probe spots on a wafer under inspection. The interactions of the primary electrons with the wafer may result in secondary particle beams being formed. The secondary particle beams may comprise backscattered electrons, secondary electrons, or Auger electrons, etc. resulting from the interactions of the primary electrons with the wafer. Characteristics of the secondary particle beams (e.g., intensity) may vary based on the properties of the internal or external structures or materials of the wafer, and thus may indicate whether the wafer includes defects.

The intensity of the secondary particle beams may be determined using a detector. The secondary particle beams may form beam spots on a surface of the detector. The detector may generate electrical signals (e.g., a current, a charge, a voltage, etc.) that represent intensity of the detected secondary particle beams. The electrical signals may be measured with measurement circuitries which may include further components (e.g., analog-to-digital converters) to obtain a distribution of the detected electrons. The electron distribution data collected during a detection time window, in combination with corresponding scan path data of the primary electron beam incident on the wafer surface, may be used to reconstruct images of the wafer structures or materials under inspection. The reconstructed images may be used to reveal various features of the internal or external structures or materials of the wafer and may be used to reveal defects that may exist in the wafer.

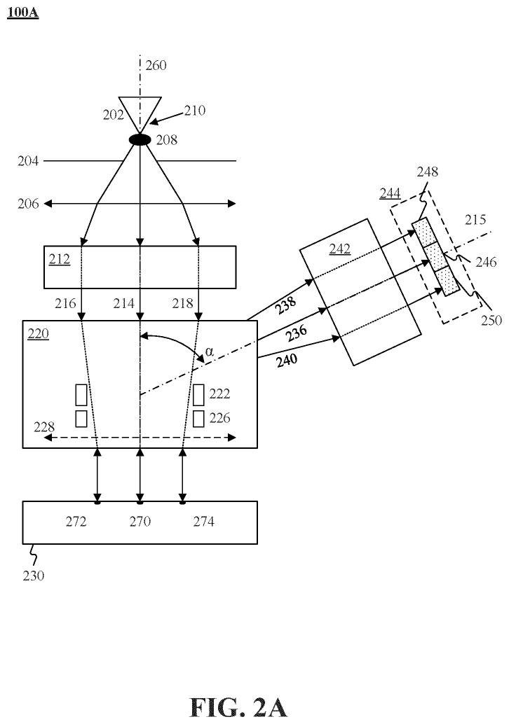

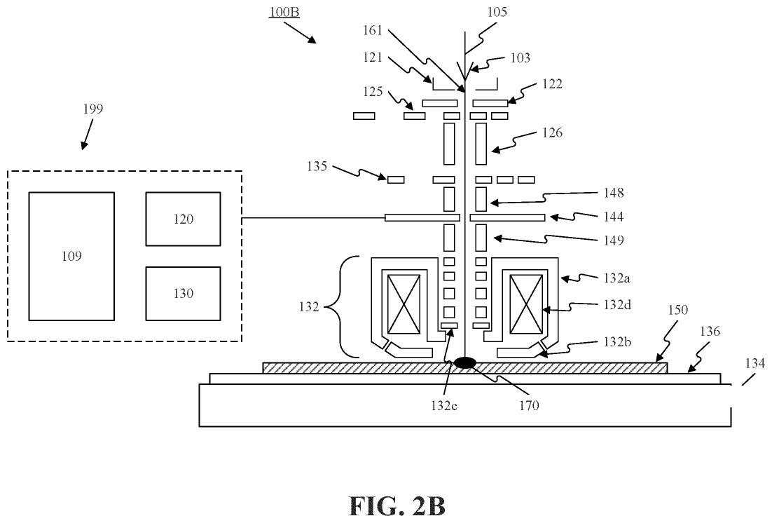

FIG. 2A illustrates a charged particle beam apparatus that may be an example of electron beam tool 100, consistent with embodiments of the present disclosure. FIG. 2A shows an apparatus that uses a plurality of beamlets formed from a primary electron beam to simultaneously scan multiple locations on a wafer.

As shown in FIG. 2A, electron beam tool 100A may comprise an electron source 202, a gun aperture 204, a condenser lens 206, a primary electron beam 210 emitted from electron source 202, a source conversion unit 212, a plurality of beamlets 214, 216, and 218 of primary electron beam 210, a primary projection optical system 220, a wafer stage (not shown in FIG. 2A), multiple secondary electron beams 236, 238, and 240, a secondary optical system 242, and electron detection device 244. Electron source 202 may generate primary particles, such as electrons of primary electron beam 210. A controller, image processing system, and the like may be coupled to electron detection device 244. Primary projection optical system 220 may comprise beam separator 222, deflection scanning unit 226, and objective lens 228. Electron detection device 244 may comprise detection sub-regions 246, 248, and 250.

Electron source 202, gun aperture 204, condenser lens 206, source conversion unit 212, beam separator 222, deflection scanning unit 226, and objective lens 228 may be aligned with a primary optical axis 260 of apparatus 100A. Secondary optical system 242 and electron detection device 244 may be aligned with a secondary optical axis 215 of apparatus 100A.

Electron source 202 may comprise a cathode, an extractor or an anode, wherein primary electrons can be emitted from the cathode and extracted or accelerated to form a primary electron beam 210 with a crossover (virtual or real) 208. Primary electron beam 210 can be visualized as being emitted from crossover 208. Gun aperture 204 may block off peripheral electrons of primary electron beam 210 to reduce size of probe spots 270, 272, and 274.

Source conversion unit 212 may comprise an array of image-forming elements (not shown in FIG. 2A) and an array of beam-limit apertures (not shown in FIG. 2A). An example of source conversion unit 212 may be found in U.S. Pat. No. 9,691,586; U.S. Publication No. 2017/0021543; and International Application No. PCT/EP2017/084429, all of which are incorporated by reference in their entireties. The array of image-forming elements may comprise an array of micro-deflectors or micro-lenses. The array of image-forming elements may form a plurality of parallel images (virtual or real) of crossover 208 with a plurality of beamlets 214, 216, and 218 of primary electron beam 210. The array of beam-limit apertures may limit the plurality of beamlets 214, 216, and 218.

Condenser lens 206 may focus primary electron beam 210. The electric currents of beamlets 214, 216, and 218 downstream of source conversion unit 212 may be varied by adjusting the focusing power of condenser lens 206 or by changing the radial sizes of the corresponding beam-limit apertures within the array of beam-limit apertures. Condenser lens 206 may be an adjustable condenser lens that may be configured so that the position of its first principal plane is movable. The adjustable condenser lens may be configured to be magnetic, which may result in off-axis beamlets 216 and 218 landing on the beamlet-limit apertures with rotation angles. The rotation angles change with the focusing power and the position of the first principal plane of the adjustable condenser lens. In some embodiments, the adjustable condenser lens may be an adjustable anti-rotation condenser lens, which involves an anti-rotation lens with a movable first principal plane. An example of an adjustable condenser lens is further described in U.S. Publication No. 2017/0021541, which is incorporated by reference in its entirety.

Objective lens 228 may focus beamlets 214, 216, and 218 onto a wafer 230 for inspection and may form a plurality of probe spots 270, 272, and 274 on the surface of wafer 230. Secondary electron beamlets 236, 238, and 240 may be formed that are emitted from wafer 230 and travel back toward beam separator 222.

Beam separator 222 may be a beam separator of Wien filter type generating an electrostatic dipole field and a magnetic dipole field. In some embodiments, if they are applied, the force exerted by electrostatic dipole field on an electron of beamlets 214, 216, and 218 may be equal in magnitude and opposite in direction to the force exerted on the electron by magnetic dipole field. Beamlets 214, 216, and 218 can therefore pass straight through beam separator 222 with zero deflection angle. However, the total dispersion of beamlets 214, 216, and 218 generated by beam separator 222 may also be non-zero. Beam separator 222 may separate secondary electron beams 236, 238, and 240 from beamlets 214, 216, and 218 and direct secondary electron beams 236, 238, and 240 towards secondary optical system 242.

Deflection scanning unit 226 may deflect beamlets 214, 216, and 218 to scan probe spots 270, 272, and 274 over an area on a surface of wafer 230. In response to incidence of beamlets 214, 216, and 218 at probe spots 270, 272, and 274, secondary electron beams 236, 238, and 240 may be emitted from wafer 230. Secondary electron beams 236, 238, and 240 may comprise electrons with a distribution of energies including secondary electrons and backscattered electrons. Secondary optical system 242 may focus secondary electron beams 236, 238, and 240 onto detection sub-regions 246, 248, and 250 of electron detection device 244. Detection sub-regions 246, 248, and 250 may be configured to detect corresponding secondary electron beams 236, 238, and 240 and generate corresponding signals used to reconstruct an image of the surface of wafer 230.

The generated signals may represent intensities of secondary electron beams 236, 238, and 240 and may be provided to an image processing system (e.g. such as image processing system 199 provided in FIG. 2B below) that is in communication with detection device 244, primary projection optical system 220, and motorized wafer stage. The movement speed of motorized wafer stage may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary electron beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary electron beams 236, 238, and 240 that may have different intensities. Therefore, by mapping the intensity of secondary electron beams 236, 238, and 240 with the areas of wafer 230, the image processing system may reconstruct an image that reflects the characteristics of internal or external structures of wafer 230.

Detection sub-regions 246, 248, and 250 may include separate detector packages, separate sensing elements, or separate regions of an array detector. In some embodiments, each detection sub-region may include a single sensing element.

Another example of a charged particle beam apparatus will now be discussed with reference to FIG. 2B. An electron beam tool 100B (also referred to herein as apparatus 100B) may be an example of electron beam tool 100 and may be similar to electron beam tool 100A shown in FIG. 2A. However, different from apparatus 100A, apparatus 100B may be a single-beam tool that uses only one primary electron beam to scan one location on the wafer at a time.

As shown in FIG. 2B, apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In a detection or imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may be communicatively coupled with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as image averaging, generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 149.

In some embodiments, the quadrupole lenses may be used for controlling the electron beam. For example, first quadrupole lens 148 may be controlled to adjust the beam current and second quadrupole lens 149 may be controlled to adjust the beam spot size and beam shape.

FIG. 2B illustrates a charged particle beam apparatus that may use a single primary beam configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150. FIG. 2B shows an example of detector 144 having an opening at its center. However, some embodiments may use a detector placed off-axis relative to the optical axis along which the primary electron beam travels. For example, as in the embodiment shown in FIG. 2A, discussed above, a beam separator 222 may be provided to direct secondary electron beams toward a detector placed off-axis. Beam separator 222 may be configured to divert secondary electron beams by an angle α toward an electron detection device 244, as shown in FIG. 2A.

A detector in a charged particle beam system may include one or more sensing elements. The detector may comprise a single-element detector or an array with multiple sensing elements. The sensing elements may be configured for charged particle counting. Sensing elements of a detector that may be useful for charged particle counting are discussed in U.S. Publication No. 2019/0379682, which is incorporated by reference in its entirety.

Sensing elements may include a diode or an element similar to a diode that may convert incident energy into a measurable signal. For example, sensing elements in a detector may include a PIN diode. Throughout this disclosure, sensing elements may be represented as a diode, for example in the figures, although sensing elements or other components may deviate from ideal circuit behavior of electrical elements such as diodes, resistors, capacitors, etc.

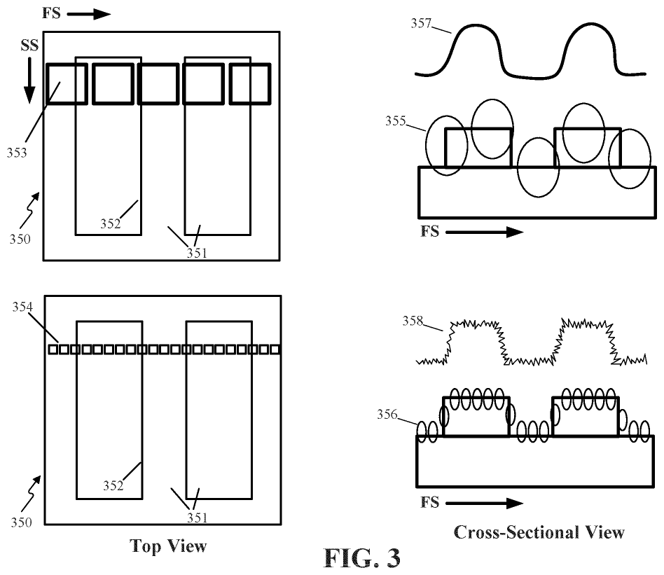

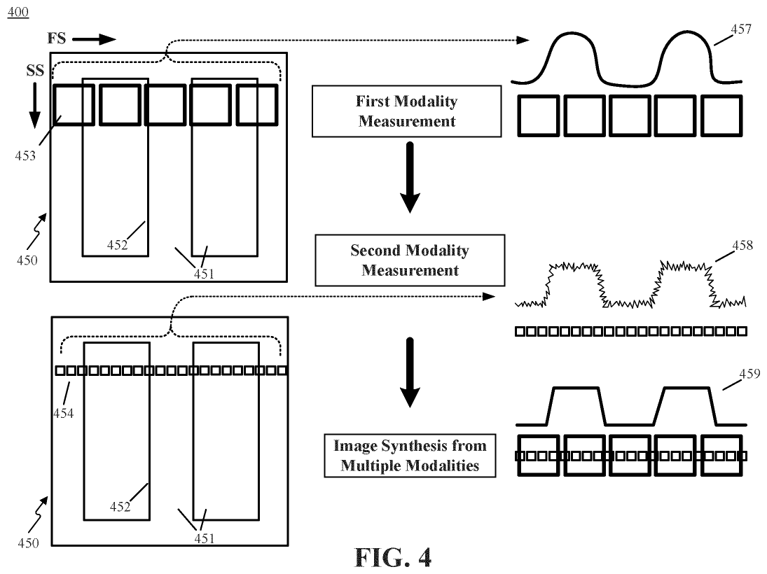

FIG. 3 illustrates first and second example signal acquisition modalities 353 and 354, consistent with embodiments of the present disclosure. First and second signal acquisition modalities 353-354 may be employed in an inspection apparatus such as, e.g., electron beam tool 100 of FIG. 1, electron beam tool 100A of FIG. 2A, or electron beam tool 100B of FIG. 2B. FIG. 3 shows top and cross-sectional views of a region of a sample 350 under inspection. For example, the sample 350 may be a semiconductor wafer and the region may be a field of view of the inspection apparatus. In FIG. 3, as in further example embodiments such as FIGS. 4-6, sample 350 (or samples 450/550/650) may comprise a vertical line/space pattern for illustrative purposes. The line/space pattern may comprise a plurality of substantially flat regions 351 separated by edge features 352. In practice, signal acquisition modalities may be applied to inspection of any sample, including integrated circuits, other semiconductor devices, photomasks, or other samples.

Under first signal acquisition modality 353, sample 350 may be irradiated with a charged particle beam by scanning large pixel areas successively in a row along a fast scan direction FS. The charged particle beam and the sample may be relatively displaced by electrical or mechanical means in a slow scan direction SS to irradiate a subsequent row of large pixel areas until substantially the entire region has been inspected under the first signal acquisition modality 353. Second signal acquisition modality 354 may be employed in a similar manner to first signal acquisition modality 353, but may correspond to, e.g., smaller pixel areas as seen in FIG. 3. The two signal acquisition modalities may be further distinguished as discussed below. It should be noted that adjacent large pixel areas of first signal acquisition modality 353 are depicted as being in a spaced relationship for clarity. In some embodiments, the large pixel areas may abut or overlap each other in the fast scan direction FS or the slow scan direction SS. Similarly, while adjacent small pixel areas of second signal acquisition modality 354 are depicted as being in a spaced relationship for clarity, in some embodiments, the small pixel areas may abut or overlap each other in the fast scan direction FS or the slow scan direction SS. It should further be understood that the illustrated pixel areas, along with their corresponding interaction volumes 355/356 and signal profiles 357/358, are highly schematic in nature and are provided for illustrative purposes.

The size of pixel areas in first or second signal acquisition modalities 353 or 354 may depend on the sizes and other properties of the corresponding interaction volumes 355 and 356 that result from the selected inspection parameters of the signal acquisition modalities. The interaction volume may be thought of as the volume of material, at and below the surface of sample 350, within which incident charged particles interact with the material of sample 350 to generate secondary charged particles. For an electron beam tool, the secondary charged particles may comprise, e.g., secondary electrons, backscattered electrons, Auger electrons, etc. A larger interaction volume may produce a larger number of secondary electrons at a detector surface, which originate from a relatively large area of the sample. Larger interaction volumes may therefore correspond to higher signal strength/higher SNR and a more rapid signal acquisition time. However, the larger interaction volume may also result in a poor imaging resolution. Thus, an inspection scan under first signal acquisition modality 353 may result in a lower noise, lower resolution signal profile 357. On the other hand, a smaller interaction volume may produce a smaller number of secondary electrons at a detector surface, which originate from a relatively small area of the sample. Smaller interaction volumes may therefore correspond to higher imaging resolution. However, the smaller number of secondary electrons may be difficult to distinguish from system noise, resulting in poor SNR and longer signal acquisition time. Thus, an inspection scan under second signal acquisition modality 354 may result in a higher noise, higher resolution signal profile 358.

Inspection tool parameters that may have a significant effect on interaction volume include beam current, accelerating voltage, landing energy, and beam incidence angle. For example, first signal acquisition modality 353 may produce larger interaction volumes 355 using a relatively higher beam current, higher accelerating voltage or landing energy, or lower or normal incidence angle. Second signal acquisition modality 354 may produce smaller interaction volumes 356 using a relatively lower beam current, lower accelerating voltage or landing energy, or higher incidence angle.

In some embodiments, first and second signal acquisition modalities 353 and 354 may differ in ways other than interaction volume, resolution, SNR, pixel size or acquisition speed. In general, scanning a sample under any number of different inspection tool settings may yield additional valuable information about a sample in view of the differing signal profiles that each modality produces. When subjected to an image synthesis process such as those discussed later below, many signal acquisition modalities may be combined to produce enhanced, higher quality inspection images. Inspection tool settings may include, e.g., beam current, landing energy, accelerating voltage, beam incidence angle, probe spot size, wafer orientation/beam scanning angle, field of view size and shape, beam aperture settings, lens aberration values, focus, lens/deflector or other charged particle optics settings, or other charged particle inspection tool parameters.

Furthermore, some embodiments of the present disclosure are described with respect to only two signal acquisition modalities, such as first and second signal acquisition modalities 353 and 354 discussed above. However, embodiments of the present disclosure are not limited to this. For example, while some measurement schemes according to embodiments of the present disclosure are discussed only with respect to first and second signal acquisition modalities, more than two may be utilized. For example, a measurement scheme may employ 2, 3, 4 . . . up to an arbitrary number (N) of unique signal acquisition modalities.

FIG. 4 illustrates an example measurement scheme 400, consistent with embodiments of the present disclosure. Measurement scheme 400 may be performed using an inspection apparatus such as, e.g., electron beam tool 100 of FIG. 1, electron beam tool 100A of FIG. 2A, or electron beam tool 100B of FIG. 2B.

Measurement scheme 400 may comprise a first measurement of a region of sample 450 under a first signal acquisition modality 453, and a second measurement of the region under a second signal acquisition modality 454. In other words, the same region of sample 450 may be scanned under multiple signal acquisition modalities. In some embodiments, the region may comprise a field of view of the inspection tool. In some embodiments, the region may comprise a portion of the field of view, such as a single scan line, a plurality of scan lines, or a portion of a scan line.

For example, measurement scheme 400 may comprise: performing a scanning measurement of a first scan line under first signal acquisition modality 453; and performing a scanning measurement of the first scan line under second signal acquisition modality 454. Some embodiments may comprise further scans up to an Nth scanning measurement of the first scan line under an Nth signal acquisition modality. Sample 450 may then be displaced relative to the charged particle beam spot in a slow scan direction SS, and the process may be repeated on a second scan line until, e.g., a full field of view is scanned under all signal acquisition modalities. In some embodiments, the entire field of view may be scanned under one signal acquisition modality before proceeding to scan the entire field of view under the next signal acquisition modality.

First signal acquisition modality 453 may be configured for, e.g., a lower resolution, lower noise, faster measurement (similar to first signal acquisition modality 353 of FIG. 3) to yield a first signal profile 457. Second signal acquisition modality 454 may be configured for, e.g., a higher resolution, higher noise, slower measurement (similar to second signal acquisition modality 354 of FIG. 3) to yield a second signal profile 458.

An image synthesis may be performed using first and second signal profiles 457 and 458 to produce an enhanced synthetic image 459 of the surface of sample 450. Synthetic images 459 may be used in, e.g., an inspection process, such as a metrology process, mask or wafer defect inspection, etc.

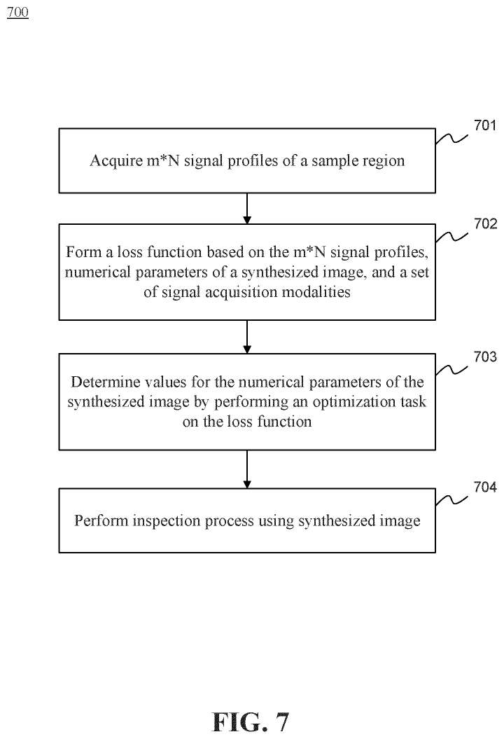

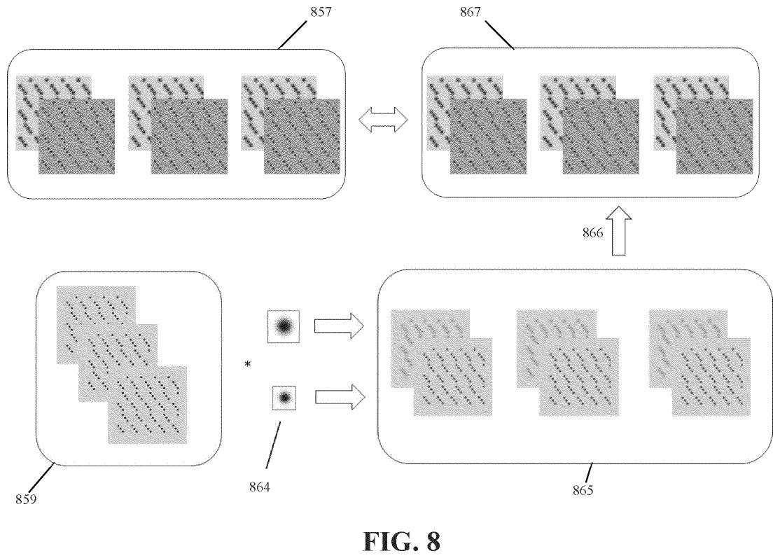

The image synthesis may comprise solving a convex or non-convex optimization task (as discussed with respect to FIGS. 7-8 below). In some embodiments, the optimization task may comprise a deconvolution task configured to reduce or eliminate system noise, aberrations or other unwanted imaging effects.

In the discussion of FIG. 4 above, it is said that the “same” region may be scanned under first and second image acquisition modalities. However, as discussed with respect to FIG. 3 and shown in FIG. 4, the regions irradiated in a single scan line under different signal acquisition modalities may not be identical if the interaction volumes and resulting pixel areas are substantially different. As discussed herein, in some embodiments, two signal acquisition modalities may be considered to irradiate the same region if, e.g., an inspection beam spot or resulting interaction volume is substantially centered on the same region in at least one planar direction. For example, FIG. 4 shows two linear scans having significantly different widths in the slow scan direction SS, yet their center positions in the slow scan direction SS are substantially the same. Thus, the first and second signal acquisition modalities 453 and 454 may be said to irradiate the same region.

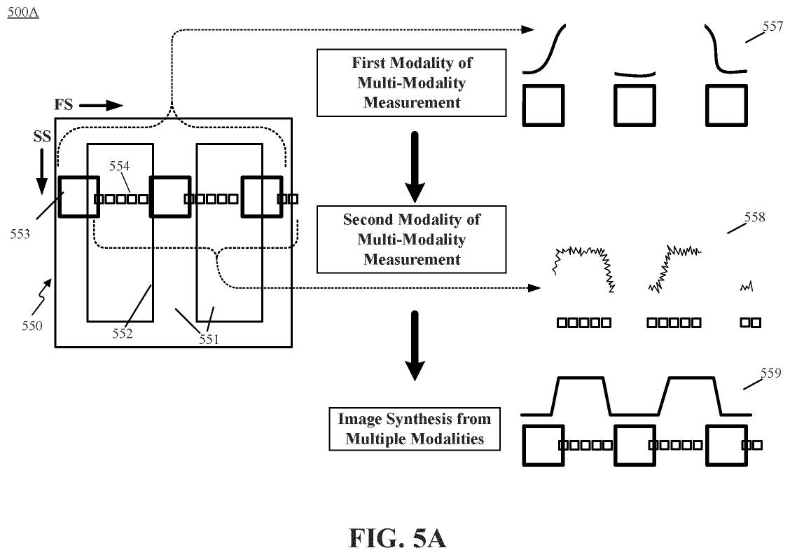

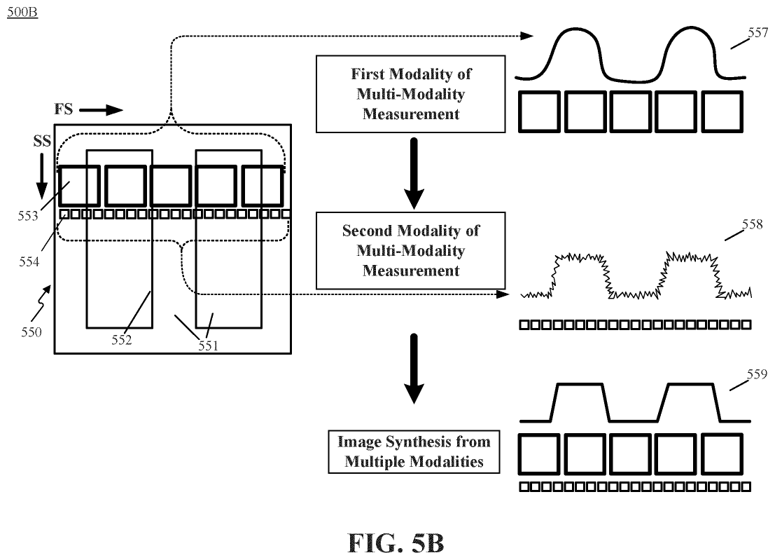

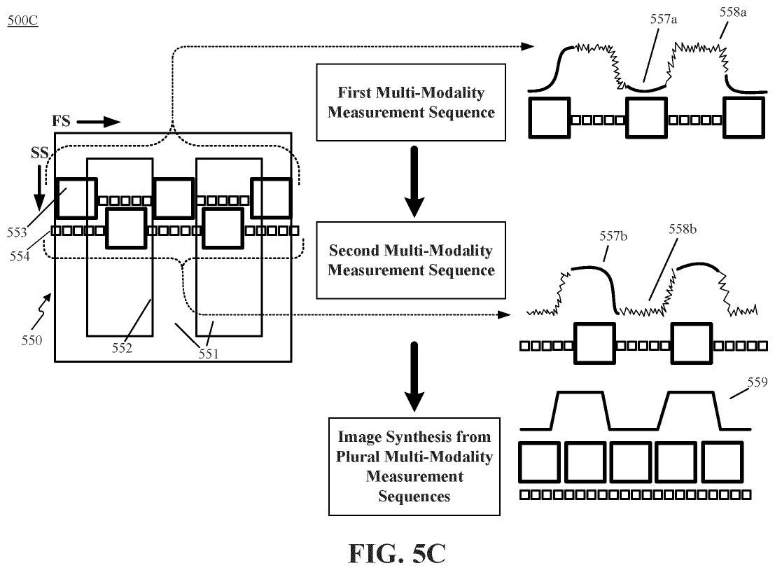

While the example of FIG. 4 may achieve superior quality inspection images 459, in some embodiments it may be desirable to scan a sample with less redundancy. For example, whereas some embodiments of measurement scheme 400 may comprise scanning the same portion of sample 450 under multiple signal acquisition modalities, in some embodiments it may be desirable to scan different portions of a sample surface with different sets of signal acquisition modalities. The resulting partial signal profiles may then be synthesized to form higher resolution images with higher throughput. Some examples of such embodiments are described below with respect to FIGS. 5A-C.

FIGS. 5A-C illustrate example measurement schemes 500A-C, consistent with embodiments of the present disclosure. Measurement schemes 500A-C may be similar to measurement scheme 400 except as described below. In particular, some embodiments of measurement schemes 500A-C may comprise multi-modality measurements in which different regions of a sample 550 surface may be measured under different signal acquisition modalities.

Measurement scheme 500A of FIG. 5A may comprise performing a multi-modality measurement sequence. For example, the multi-modality measurement sequence may comprise first and second signal acquisition modalities 553/554 similar to those modalities 353/354 of FIG. 3 or modalities 453/454 of FIG. 4. However, instead of scanning a full region under a single modality (such as a full scan line or full field of view), the multi-modality measurement sequence may switch between signal acquisition modalities in real time during the scan. The resulting signal profile is shown at the right of FIG. 5A as a set of partial signal profiles 557 and 558. Partial signal profile 557 may represent those segments of the sample 550 that were scanned under a first (e.g., lower resolution, lower noise, faster) signal acquisition modality 553. Partial signal profile 558 may represent those segments of the sample 550 that were scanned under a second (e.g., higher resolution, higher noise, slower) signal acquisition modality 554. The partial signal profiles 557 and 558 may be synthesized to form synthetic image 559 using, e.g., an optimization task. Synthetic image 559 may have a higher resolution than would be achievable by, e.g., scanning the entire region under first signal acquisition modality 553. Further, synthetic image 559 may have less noise and a faster acquisition time than would be achievable by, e.g., scanning the entire region under second signal acquisition modality 554. In some embodiments, the synthesis of two or more partial signal profiles may yield a synthetic image in which substantially all image characteristics are superior to those any individual signal acquisition modality.

In measurement scheme 500B of FIG. 5B, the multi-modality measurement sequence may alternate in a slow scan direction SS instead of a fast scan direction FS. For example, a first line may be scanned under first signal acquisition modality 553, and a second line may be scanned under second signal acquisition modality 554. Signal profiles 557 and 558 may then be synthesized to form a higher resolution, lower noise synthetic image 559. Unlike the example in FIG. 4, in which a same region was scanned multiple times, measurement scheme 500B may scan adjacent or partially overlapping regions under different signal acquisition modalities in sequence. This may achieve an enhanced image 559 with greater throughput.

Further, as shown in FIG. 5C, measurement scheme 500C may comprise a plurality of multi-modality measurement sequences that alternate in both the fast scan FS and slow scan SS directions.

For example, first and second signal acquisition modalities 553 and 554 may be alternated in a plurality of complimentary sequences. An inspection apparatus may, e.g., irradiate a first scan line of sample 550 under a first multi-modality measurement sequence, and may scan a second scan line of sample 550 under a second multi-modality measurement sequence. In some embodiments, the first and second multi-modality measurement sequences may be complimentary to ensure that adjacent areas in the fast scan FS and the slow scan direction SS are measured under different signal acquisition modalities. For instances, the sequences may be arranged to create a checkerboard or other 2D pattern.

The first multi-modality measurement sequence may yield a plurality of first partial signal profiles 557a/558a, and the second multi-modality measurement sequence may yield a plurality of second partial signal profiles 557b/558b. An image synthesis may be used to merge all partial signal profiles to create synthetic image 559.

While embodiments of the present disclosure schematically depict immediate transitions between first and second signal acquisition modalities, in practice this may not always be the case. In some embodiments the change may be more gradual due to, e.g., a mismatch between a scan speed in the fast scan direction FS and the time required to transition between inspection tool settings of first and second signal acquisition modalities. In some embodiments, this gradual transition may comprise, or be represented by, one or more discrete signal acquisition modalities whose parameters take values between those of the signal acquisition modalities on either side of it. For example, the act of switching between a first (lower resolution, lower noise, faster) signal acquisition modality and a second (higher resolution, higher noise, slower) signal acquisition modality may comprise a period that may be represented by a third (medium resolution, medium noise, medium speed) signal acquisition modality. Alternatively, the transition may comprise intentionally setting the inspection apparatus to the third signal acquisition modality. Such transition modalities may allow a measurement scheme to be performed with greater knowledge of the tool settings at each exposure pixel, thus enabling improved modeling and synthesis of acquired signal profiles.

The multi-modality sequences of FIGS. 5A-C are depicted as being regularly repeating and binary, however this is not necessarily the case. Some embodiments may comprise sequences of 2, 3, 4 . . . up to an arbitrary number (N) of signal acquisition modalities. The sequences may be simple and monotonic (such as 1-2-3-1-2-3, 1-1-2-2-2, etc.), or may be more complex and oscillatory (such as 1-2-1-3-1-4-1-3-1-2, etc.). In some embodiments, the multi-modality measurement may have no repeating or discernible sequence. For example, the inspection apparatus may be configured to alternate between different signal acquisition modalities in a random or pseudo-randomized manner.

Further, in some embodiments, as seen in FIG. 5A, the multi-modality measurement sequences may not correspond to a sequence of pattern features on the sample. For example, the repetition periods of multi-modality measurement sequences may not align with repetition periods of the pattern features under inspection. This may be advantageous, as it allows different segments of a repeating pattern to be scanned under different signal acquisition modalities. However, in other embodiments, a multi-modality measurement sequence may be designed to conform to the pattern under inspection. For example, a multi-modality measurement sequence may be configured to irradiate flat regions 551 with first signal acquisition modality 553 and edge features 552 with second signal acquisition modality 554.

In some embodiments, a multi-modality measurement sequence may be designed based on known information such as GDS files or other pattern design data. In some embodiments, a pixel brightness measured at a first point may be used to infer information about a pattern characteristic under inspection (e.g., a flat vs edge region, a material characteristic, surface height or other topography) at subsequent point. A dynamic multi-modality measurement sequence may be determined or adjusted in real-time, or on a per-sample or per-lot basis. The dynamic determinations may be made based on, e.g., feedforward or feedback information, machine learning training sets, or deep learning systems. In some embodiments, a reference region or a refence sample may be scanned under a coarse signal acquisition modality (such as a lower resolution, faster acquisition modality 553) to identify critical feature areas for scanning under a fine signal acquisition modality (such as a higher resolution, slower acquisition modality 554).

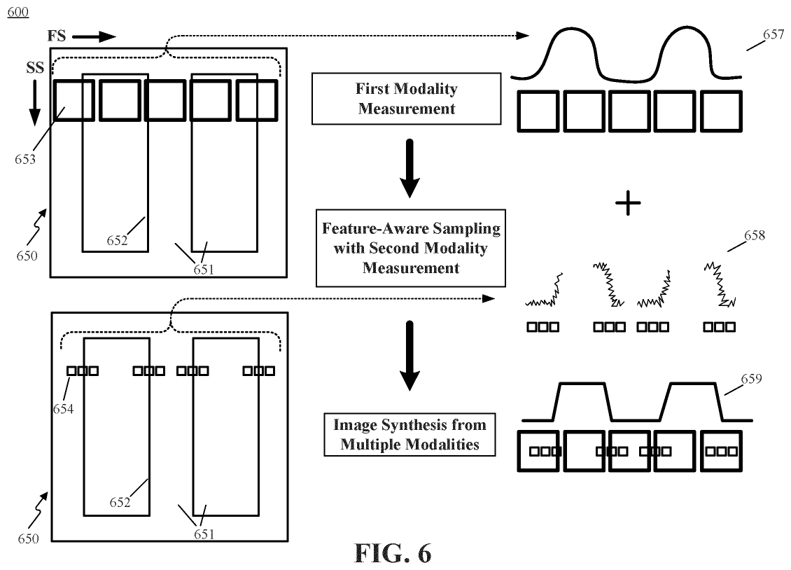

For example, FIG. 6 illustrates a further example measurement scheme 600, consistent with embodiments of the present disclosure. Measurement scheme 600 may comprise feature-aware sampling under a second signal acquisition modality 654 based on information obtained under a first signal acquisition modality 653. For instance, a first scan of a region of sample 650 may take place under first signal acquisition modality 653 to roughly distinguish critical edge features 652 from flat regions 651. The first scan may comprise scanning an entire field of view or only selected portions of it. In some embodiments, the first scan may take place on a different field of view or on a different sample from a second scan under second signal acquisition modality 654. In some embodiments, GDS files or other pattern design data may be used alternatively, or in addition to, the first scan.

The second scan under second signal acquisition modality 654 may then be applied only to those areas at which a critical feature 652 is expected to be found. In this way, throughput may be improved by reserving lower speed, higher resolution modalities only for those areas where it is deemed necessary. Noise components in high-resolution signal profile 658 may be mitigated by image synthesis with the lower noise signal profile 657 to yield enhanced synthetic image 659.

In some embodiments, a pattern-aware sampling or other multi-modality measurement sequence may be designed to accommodate sensitive structures on a sample surface. For example, some components of a sample may be prone to damage if irradiated under a higher beam current. Therefore, any of the above discussed measurement schemes may be used to switch from, e.g., a high-current to low-current signal acquisition modality at sensitive structures. By reserving the slower signal acquisition modalities only for those areas that require lower beam currents, throughput may be increased.

In some embodiments of the present disclosure, knowledge of flat regions 651 may be used to identify noise components in the acquired signal profiles. For example, by scanning the same or similar flat regions 651 of a sample surface under a plurality of signal acquisition modalities, or within a plurality of locations within a field of view, it may be possible to better decouple aberrations and system noise components from the measurements.

FIG. 7 is a flowchart illustrating a method 700 that may be useful for producing a synthetic image from a plurality of signal acquisition modalities using an optimization task, consistent with embodiments of the disclosure. Method 700 may be performed using, e.g., electron beam tool 100 of FIG. 1, electron beam tool 100A of FIG. 2A, or electron beam tool 100B of FIG. 2B. For example, some method steps may be performed using a controller such as, e.g., controller 109 of FIG. 1, or image acquisition unit 199 of FIG. 2B. In some embodiments, method 700 may be performed in conjunction with, e.g., any of measurement schemes 400-600 of FIGS. 4-6 respectively.

At step 701, N locations on a sample may be irradiated, each under m signal acquisition modalities to acquire m*N signal profiles as images of regions on a sample surface. Each signal acquisition modality may correspond to a unique set of inspection tool settings as discussed above. In some embodiments, different signal acquisition modalities may correspond to different regions within each of the N locations. For example, in some embodiments a location may correspond to a field of view of the sample, and each region may correspond to the portion of the field of view that is irradiated under a particular signal acquisition modality. Note that in some embodiments, not every location may be irradiated under the same numbers or types of signal acquisition modalities.

In steps 702, 703, the m*N signal profiles acquired in step 701 may be used, in combination with the signal acquisition modalities under which the m*N signal profiles were captured, to determine numerical values of a synthetic image. Specifically, in step 702 a loss function may be formed based on the numerical parameters of the synthetic image, the acquired signal profiles and the signal acquisition modalities. In step 703, the numerical parameters of the synthetic image may be determined by minimizing the loss function with respect to the numerical parameters of the synthetic image (and optionally with respect to other parameters also, as described below).

In step 704, using the synthetic image, an inspection process such as metrology or defect inspection may be performed. For example, it is determined whether the product model meets an anomaly criterion indicative of the presence of a defect. Optionally, the location of the defect on the region of the sample may also be estimated. If a defect is detected, further metrology and/or defect inspection may be performed. Alternatively or additionally, step 704 may include metrology (measurements) on the product model.

An example application of method 700 of FIG. 7 is further explained with respect to FIG. 8. In step 701, a plurality of signal profiles may be acquired under a plurality of signal acquisition modalities. Each signal profile may constitute an acquired image of a region on a location of a sample. FIG. 8 shows three acquired signal profile images 857. For instance, the images may be acquired according to, e.g., measurement scheme 400 of FIG. 4, and may correspond to a region on a field of view of a sample. The signal acquisition modalities may comprise a first signal acquisition modality configured to produce a larger interaction volume and a second signal acquisition modality configured to produce a smaller interaction volume. The first signal acquisition modality may be configured for higher acquisition speed, higher SNR and lower resolution. The second signal acquisition modality may be configured for lower acquisition speed, lower SNR and higher resolution. Thus images 857 may, e.g., be blurred and have poor spatial resolution, or may have higher resolution but a poor SNR. The acquired images are denoted {Pₖ}, where k is an integer index, k=l, . . . (m*N), N is the number of locations imaged, and m is the number of distinct signal acquisition modalities within each of the N images.

Each acquired image 857 may comprise an n×n array of pixels, where n is an integer (for simplicity, square arrays of pixels are considered, but in some embodiments the arrays need not be square), and each pixel may be associated with a respective brightness value.

The synthetic image in this example of method 700 may comprise a set of m*N images depicted in FIG. 8 as 859, having, e.g., a one-to-one correspondence to the acquired images 857. Each image 859 may comprise a p×p array of pixels where p is an integer, with each pixel being associated with a brightness value. The brightness values for all images 859 may collectively form the numerical values of the synthetic image. The images 859 may be referred to as “reconstructed” images. The reconstructed images are denoted {Xₖ}. Reconstructed images 859 may have higher resolution or SNR than acquired images 857. Furthermore, p may be greater than n. Reconstructed images 859 may have a higher pixel resolution than acquired images 857, in that a given distance on the sample region may span a greater number of pixels of reconstructed images 859 than of acquired images 857.

The imaging model in this case may include a set of convolutions (or any physics-based model capable of representing a model of the imaging system used to acquire the images 857) 864 that are assumed to be known, as each convolution 864 may correspond to the settings of a particular signal acquisition modality. Alternatively, the set of convolutions 864 could be taken as an unknown that may be learned from available data. In such a case, the set of convolutions or other models 864 may be part of the optimization problem. Convolutions 864 may each apply a different blurring defined by point spread functions Bᵢ, which may be two-dimensional arrays of values (kernels), followed by a pixel resolution reduction process 866 of reducing the pixel dimension to n×n. In other words, the m*N reconstructed images 859 are images such that, if they are convolved with the appropriate kernel B, resulting in m*N respective arrays 865 of convolved values (which may also have size p×p), and if the pixel dimension of the each of the arrays 865 is reduced to n×n to generate m*N images 867 resembling corresponding ones of the acquired images (e.g., by being blurred, having a lower spatial resolution or SNR, etc.). Here these m*N images 867 may be referred to as “corrupted images.” Note that each of the corrupted images 867 may correspond to one of the acquired images 857, and may be an image of the same region on the sample under inspection.

In one simple form of the pixel resolution reduction process 866, p may be a multiple of n (e.g., p=an where a is an integer), so that each pixel of the images 867 corresponds to a respective a×a patch of pixels of the convolved arrays 865. Thus, to perform the pixel resolution reduction process 866, the brightness value of each pixel of each corrupted image 867 may be obtained as the average of the brightness of the corresponding patch of the convolved array 865.

The reconstructed images 859 may be thought of as the brightness images that would be obtained if the sample region were imaged by a higher resolution, lower SNR imaging process than the one which produced the corresponding images 857.

In principle, a large number of possible sets of reconstructed images 859 have the property shown in FIG. 8 (e.g., the problem of using acquired images 857 to form reconstructed images 859 may be ill-posed). However, this application of the method 700 assumes that there is some a priori knowledge about the reconstructed images 859. Firstly, the reconstructed images 859 are known to be limited in complexity, having a relatively small number of top-down features visible on a patterned stack. Also, the expected device structures may have a smooth local variation (e.g., the patterned lines are formed out of material blobs and not sharp features). In addition, there may be similarities between the reconstructed images 859 since their corresponding imaging areas may contain the same structure or similar structures. This prior knowledge may be used to define terms of a loss function as a function of the reconstructed images 859 (and of the acquired images 857 and the signal acquisition modalities), such that minimizing the loss function with respect to the reconstructed images 859 ensures that the reconstructed images 859 are in accordance with this prior knowledge, and also match the measured data via the process exemplified in FIG. 8.

Specifically, the loss function may be of the form:

$$ℒ ( \{ {X}_{k} \} ) = {\sum }_{k , i} {‖ {M}_{i} {F}^{- 1} ( {FX}_{k} \cdot {FB}_{i} ) - {P}_{k , i} ‖}_{F}^{2} + α {\sum }_{k} {‖ [ {WX}_{k} ; {D}_{TV} {X}_{k} ; {X}_{k} ] ‖}_{1}^{1} + β {‖ [ {DX}_{1} , {DX}_{2} , … , {DX}_{N} ] ‖}^{*} \qquad ( 1 )$$

Here, the square brackets [ . . . ] denote the concatenation of the elements inside the bracket, Mᵢ denotes the i-th process 866, e.g., applying the mask and, where necessary, reducing the pixel dimension. F denotes a Fourier transform and F⁻¹ denotes an inverse Fourier transform. P_{k,i} denotes the k-th acquired image 857 under the i-th signal acquisition modality. Xₖ denotes the k-th reconstructed image 859. Thus, F⁻¹(FXₖ·FBᵢ) denotes the array of convolved values 865 obtained by applying the appropriate convolution 864 to the reconstructed image Xₖ, and MᵢF⁻¹(FXₖ·FBᵢ) denotes the corrupted images 867. In some embodiments as discussed above, the set 864 may comprise other physics-based models. In general, therefore, the array of values 865 may be achieved with, e.g., some function G(Xₖ, Bᵢ). Note that the Fourier transform—i.e., the conversion from the spatial domain to the spatial frequency domain—is employed because it is a computationally efficient way of performing the convolution operation denoted by the kernels Bᵢ, e.g., using a Fast Fourier transform (FFT) operation; in principle, the convolution operations may be implemented directly in the spatial domain, rather than by means of Fourier transforms.

$${‖ \cdot ‖}_{F}^{2}$$

denotes the Frobenius norm of a matrix, which is the squared l₂ norm of the matrix in a vector format. This quantifies the goodness of fit between the measurements and the reconstructed data.

$${\sum }_{k} {‖ [ {WX}_{k} ; {D}_{TV} {X}_{k} ; {X}_{k} ] ‖}_{1}^{1}$$

is a regularization term, including a structural term D_{TV}Xₖ. W denotes a wavelet transformation (several wavelet transformations are known; the one used in the present experiments is a wavelet transformation based on the Haar wavelet). D_{TV} denotes a well-known operator that converts Xₖ into an image gradient domain. It uses nearby pixel differences (in the horizontal, vertical and/or diagonal directions) to encode this information. ∥·∥₁¹ is the l₁ norm, e.g., the sum of the absolution values. Here it is applied to [WXₖ; D_{TV}Xₖ; Xₖ], which denotes the concatenation of WXₖ, D_{TV}Xₖ and Xₖ.

D denotes an operation of converting a matrix Xₖ into a vector. ∥·∥* denotes a nuclear norm operation. The norm is computed as the sum of the absolute singular values of the concatenation of all the vectorized images, e.g., [DX₁,DX₂, . . . , DX_{N}].

α and β are hyper-parameters, determining the relative importance of the terms in the loss function.

The minimization algorithm can then be expressed as finding:

$$arg {min}_{\{ {X}_{k} \}} ℒ ( \{ {X}_{k} \} ) subject to 0 \leq {X}_{k} \leq M for all k and all points on {X}_{k} . \qquad ( 2 )$$

If the deconvolution is performed for a single image X, the sum over k disappears. Thus, each point in Xₖ may be constrained to be in the range 0 to an upper pixel intensity limit M. The task of image recovery (e.g., obtaining the reconstructed images) may be stated as a deconvolution task with smoothness and low rank constraints.

Specifically, the term

$${\sum }_{k , i} {‖ {M}_{i} {F}^{- 1} ( {FX}_{k} \cdot {FB}_{i} ) - {P}_{k , i} ‖}_{F}^{2}$$

encourages the corrupted images 867 to resemble the acquired images 857 for ensuring data consistency. Note that Eqn. (1) formulates this property in the Fourier domain since it is easier to state the convolution task with each kernel Bᵢ as a multiplication in the spatial frequency domain.

The regularization term

$${\sum }_{k} {‖ [ {WX}_{k} ; {D}_{TV} {X}_{k} ; {X}_{k} ] ‖}_{1}^{1}$$

encourages Xₖ to include the expected features of the reconstructed images, such as areas with uniform intensity, and well-defined lines. The wavelet component WXₖ, and the component based just on Xₖ, encourage Xₖ to have a low fill ratio. The structural term D_{TV}Xₖ encourages the presence of edges. Optionally, to promote recovery of horizontal and vertical lines (on the assumption that the x and y axes in the images 857 are strongly correlated with elongation directions of elongate elements in the product), D_{TV} can be defined to give a higher weight in the vertical and horizontal directions than in diagonal directions. A step d can be introduced between pixels used in the computations (e.g. D_{TV} may be defined to compute the difference between horizontal/vertical pixels separated by a distance of d pixels where d is greater than one, rather than nearest-neighboring pixels).

The term ∥[DX₁, DX₂, . . . , DX_{N}]∥* encourages the requirement that the images Xₖ are similar, since they are images of respective areas including similar structures (e.g. based on the same design data, or design data meeting a similarity criterion). This requirement is encoded in Eqn. (1) by ensuring that the concatenated reconstructed images produce a low-rank matrix. This property is encoded via a convex relaxation of the low-rank property, namely the nuclear norm ∥DX₁, DX₂, . . . , DX_{N}]∥*.

The hyper-parameters α and β may be chosen by trial-and-error, to produce reconstructed images 859 having the desired properties. For example, if higher resolution images are available for certain products, the hyper-parameters α and β can be chosen to ensure the best match with that image. Note that the setting of hyper-parameters α and β may need to be done only once in a “set-up” phase, so it may be worthwhile to incur the costs of obtaining the higher resolution image, so that the hyper-parameter values obtained can be used thereafter in the process of FIG. 8 for examining a larger number of other products.

While the above-described optimization problem is capable of producing high-quality images, in some embodiments it may be desirable to reduce the time and computational burden required to achieve such images. For example, in some embodiments, surrogate modeling using, e.g., neural networks, may be employed to enhance the efficiency of the modeling process. The faster neural network may be fed a set of selected image pairs 857/867 as training data generated from the relatively slower optimization process above. The training set may be sampled, e.g., at predetermined values across a space of parameters of interest. Using the initial training set, the network may construct a surrogate model 864. The surrogate model may then be analyzed to identify optimal conditions for generating further training image pairs 857/867 by the slow optimization process, based on their expected improvement of the training set. The further image pairs 857/867 may then be used to enrich the training set and the process may repeat.

The surrogate modeling process may be used to construct a set of models 864 with greatly increased speed and reduced computational burden. Once trained, the surrogate models may be applied in the optimization process of FIG. 8 to more quickly produce enhanced synthetic images.

Further details of optimization tasks are discussed in European Patent Application No. EP22185297 which is incorporated by reference in its entirety.

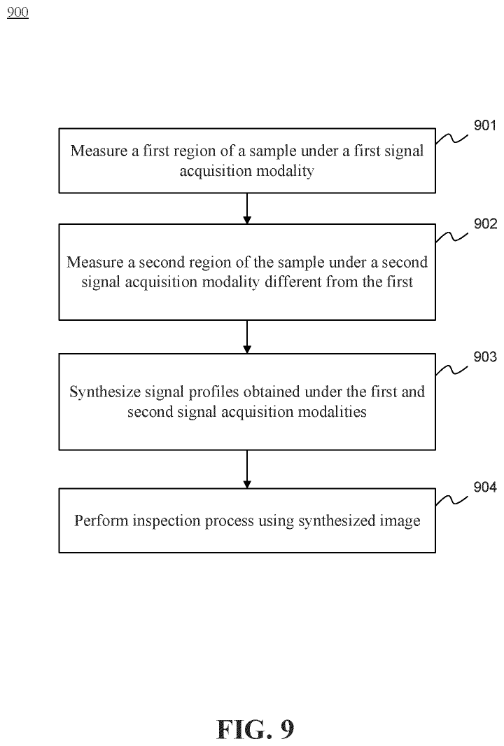

FIG. 9 is a flowchart illustrating a method 900 that may be useful for producing a synthetic image from a plurality of signal acquisition modalities, consistent with embodiments of the disclosure. Method 900 may be performed using, e.g., electron beam tool 100 of FIG. 1, electron beam tool 100A of FIG. 2A, or electron beam tool 100B of FIG. 2B. For example, some method steps may be performed using a controller such as, e.g., controller 109 of FIG. 1, or image acquisition unit 199 of FIG. 2B. In some embodiments, method 900 may be performed in conjunction with, e.g., any of measurement schemes 400-600 of FIGS. 4-6 respectively.

At step 901, an inspection tool may measure a first region of a sample under a first signal acquisition modality. The first region of the sample may be, e.g., the entire sample, a die region of the sample, a field of view of the inspection tool on the sample, a scan line or portion of a scan line on the sample. The first signal acquisition modality may be a collection of inspection tool settings. The inspection tool settings may comprise, e.g., beam current, landing energy, accelerating voltage, beam incidence angle, probe spot size, wafer orientation/beam scanning angle, field of view size and shape, beam aperture settings, lens aberration values, focus, lens/deflector or other charged particle optics settings, or other charged particle inspection tool parameters. The first signal acquisition modality may be configured to produce a desired set of imaging parameters. For example, the first signal acquisition modality may be configured to produce a relatively larger interaction volume or configured to yield, e.g., a higher acquisition speed, higher SNR, or lower resolution signal profile.

At step 902, the inspection tool may measure a second region of the sample under a second signal acquisition modality that is different from the first signal acquisition modality in at least one inspection tool setting. For example, in some embodiments the second signal acquisition modality may be configured to produce a relatively smaller interaction volume, or may be configured to yield, e.g., a lower acquisition speed, lower SNR, or higher resolution signal profile.

In some embodiments, the first and second regions may be the same. For example, the inspection tool may scan an entire line under each of the first and second signal acquisition modalities before proceeding to a next line, and may continue until the entire field of view is exposed under both signal acquisition modalities. In such a case, an individual line, the entire field of view, etc. may be considered as both the first and second regions. An example of the above-discussed embodiments may be seen in measurement acquisition scheme 400 of FIG. 4.

In some embodiments, the first and second regions may be different. For example, the first and second regions may be adjacent, may be spaced apart from one another, or may overlap slightly. For example, the first and second regions may correspond to different portions of one or more scan lines. The inspection tool may irradiate a single scan line while alternating between the first and second signal acquisition modalities in a multi-modality measurement sequence in a scanning direction (such as a fast scan direction FS as seen in FIGS. 4-6). In such a case, the portions of the line that are irradiated under the first signal acquisition modality may correspond to the first region, and the portions of the line that are irradiated under the second signal acquisition modality may correspond to the second region. Alternatively, the inspection tool may scan a plurality of lines while alternating between first and second signal acquisition modalities in a non-scanning direction (such as a slower scan direction SS as seen in FIGS. 4-6). In some embodiments, the inspection tool may employ a plurality of multi-modality sequences on different scan lines in a field of view. Examples of the above-discussed embodiments may be seen in measurement acquisition schemes 500A-C of FIGS. 5A-C.

In some embodiments, the second region may be included within the first region. For example, inspection tool may irradiate substantially an entire line or an entire field of view under the first signal acquisition modality to obtain a coarse measurement (such as a higher speed, lower resolution measurement) of the first region. Using information about a critical feature (such as information derived from the first scan, or known information such as a prior scan, GDS file or other pattern design data), the inspection tool may irradiate those areas at which the critical feature is expected to be found.

The measurements performed at steps 901 and 902 may yield signal profiles corresponding to images of the measured regions.

At step 903, the signal profiles obtained at steps 901 and 902 may be synthesized to form an enhanced, higher quality image of a portion of the sample. For example, the synthesis may comprise performing an optimization task to find a solution to the combination of signal profiles. In some embodiments, the synthesis may be stated as a deconvolution task. Examples of optimization tasks may include those discussed above with respect to FIGS. 7 and 8. In some embodiments, deep learning or machine learning techniques may be used to synthesize the image.

At step 904, the synthetic image may be used to perform an inspection process. For example, the synthetic image may be analyzed for defect detection, metrology operations, or other sample inspection processes.

A non-transitory computer-readable medium may be provided that stores instructions for a processor of a controller (e.g., controller 109 in FIG. 1, or image acquisition unit 199 in FIG. 2B) for detecting charged particles according to, e.g., measurement acquisition schemes 400-600 of FIGS. 4-6, the exemplary flowchart 700 of FIG. 7, or the exemplary flowchart 900 of FIG. 9, consistent with embodiments of the present disclosure. For example, the instructions stored in the non-transitory computer-readable medium may be executed by the circuitry of the controller for performing measurement acquisition schemes 400-600 or methods 700 or 900 in part or in entirety. Common forms of non-transitory media include, for example, a floppy disk, a flexible disk, hard disk, solid-state drive, magnetic tape, or any other magnetic data storage medium, a Compact Disc Read-Only Memory (CD-ROM), any other optical data storage medium, any physical medium with patterns of holes, a Random Access Memory (RAM), a Programmable Read-Only Memory (PROM), and Erasable Programmable Read-Only Memory (EPROM), a FLASH-EPROM or any other flash memory, Non-Volatile Random Access Memory (NVRAM), a cache, a register, any other memory chip or cartridge, and networked versions of the same.

Embodiments of the present disclosure may further be described by the following clauses:

1. A non-transitory computer-readable medium that stores a set of instructions that is executable by at least one processor of an apparatus to cause the apparatus to perform a method comprising: measuring a first region of a sample with a charged particle beam inspection apparatus under a first signal acquisition modality to obtain a first signal profile;
measuring a second region of the sample with the charged particle beam inspection apparatus under a second signal acquisition modality to obtain a second signal profile, the second signal acquisition modality being different from the first signal acquisition modality in an inspection parameter of the charged particle beam apparatus; and
generating, using an optimization task, an inspection image based on a synthesis of the first signal profile and the second signal profile.
   2. The non-transitory computer-readable medium of clause 1, wherein the first region and the second region are the same region.
   3. The non-transitory computer-readable medium of clause 1, wherein the first region is different from the second region.
   4. The non-transitory computer-readable medium of clause 3, wherein the first region and the second region do not overlap.
   5. The non-transitory computer-readable medium of clause 1, wherein the first region comprises a field of view of the charged particle beam inspection apparatus.
   6. The non-transitory computer-readable medium of clause 1, wherein:
the first region comprises a first scan line in a field of view of the charged particle beam inspection apparatus, and
the second region comprises a second scan line in the field of view of the charged particle beam inspection apparatus, the second scan line being different from the first scan line.
   7. The non-transitory computer-readable medium of clause 1, wherein:
the first region comprises a first portion of a first scan line in a field of view of the charged particle beam inspection apparatus, and
the second region comprises a second portion of the first scan line in the field of view of the charged particle beam inspection apparatus, the second portion being different from the first portion.
   8. The non-transitory computer-readable medium of clause 7, wherein the first region and the second region of the first the scan line correspond to a first multi-modality measurement sequence.
   9. The non-transitory computer-readable medium of clause 8, wherein the set of instructions that is executable by the at least one processor causes the apparatus to further perform:
measuring a third region of the sample with the charged particle beam inspection apparatus under the first signal acquisition modality to obtain a third signal profile; and
measuring a fourth region of the sample with the charged particle beam inspection apparatus under the second signal acquisition modality to obtain a fourth signal profile,
wherein generating the inspection image is further based on a synthesis of the third signal profile and the fourth signal profile.
   10. The non-transitory computer-readable medium of clause 9, wherein:
the third region comprises a third portion of a second scan line in a field of view of the charged particle beam inspection apparatus, the second scan line being different from the first scan line, and
the fourth region comprises a fourth portion of the second scan line in the field of view of the charged particle beam inspection apparatus, the fourth portion being different from the third portion.
   11. The non-transitory computer-readable medium of clause 10, wherein the third region and the fourth region of the second the scan line correspond to a second multi-modality measurement sequence different from the first multi-modality measurement sequence.
   12. The non-transitory computer-readable medium of clause 8, wherein the multi-modality measurement sequence does not correspond to a sequence of pattern features on the first region or the second region.
   13. The non-transitory computer-readable medium of clause 8, wherein the multi-modality measurement sequence corresponds to a sequence of pattern features on the first region or the second region.
   14. The non-transitory computer-readable medium of clause 13, wherein the multi-modality measurement sequence is based on prior information of the pattern features on the first region or the second region.
   15. The non-transitory computer-readable medium of clause 13, wherein the at least one processor is configured to cause the apparatus to further perform:
updating the multi-modality measurement sequence during the measurement of the first region or the second region based on information obtained from the first region or the second region.
   16. The non-transitory computer-readable medium of clause 1, wherein the second region corresponds to a sample feature within the first region.
   17. The non-transitory computer-readable medium of clause 16, wherein the sample feature comprises an expected location of a pattern edge feature.
   18. The non-transitory computer-readable medium of clause 1, wherein the first signal acquisition modality is configured to generate a larger interaction volume in the sample than the second signal acquisition modality.
   19. The non-transitory computer-readable medium of clause 1, wherein the first signal acquisition modality is configured to achieve one of a higher signal acquisition speed, a higher signal to noise ratio, or a lower resolution than the second signal acquisition modality.
   20. The non-transitory computer-readable medium of clause 1, wherein the inspection parameter of the charged particle beam apparatus comprises one of a beam current, landing energy, accelerating voltage, beam incidence angle, probe spot size, wafer orientation, beam scanning angle, field of view size, field of view shape, beam aperture setting, lens aberration value, focus value, and charged particle optics setting.
   21. The non-transitory computer-readable medium of clause 1, wherein the optimization task comprises a loss function.
   22. The non-transitory computer-readable medium of clause 1, wherein the optimization task comprises an inverse problem.
   23. The non-transitory computer-readable medium of clause 22, wherein the optimization task comprises a deconvolution task.
   24. A charged particle beam inspection method, comprising:
measuring a first region of a sample with a charged particle beam inspection apparatus under a first signal acquisition modality to obtain a first signal profile;
measuring a second region of the sample with the charged particle beam inspection apparatus under a second signal acquisition modality to obtain a second signal profile, the second signal acquisition modality being different from the first signal acquisition modality in an inspection parameter of the charged particle beam apparatus; and
generating, using an optimization task, an inspection image based on a synthesis of the first signal profile and the second signal profile.
   25. The method of clause 24, wherein the first region and the second region are the same region.
   26. The method of clause 24, wherein the first region is different from the second region.
   27. The method of clause 26, wherein the first region and the second region do not overlap.
   28. The method of clause 24, wherein the first region comprises a field of view of the charged particle beam inspection apparatus.
   29. The method of clause 24, wherein:
the first region comprises a first scan line in a field of view of the charged particle beam inspection apparatus, and
the second region comprises a second scan line in the field of view of the charged particle beam inspection apparatus, the second scan line being different from the first scan line.
   30. The method of clause 24, wherein:
the first region comprises a first portion of a first scan line in a field of view of the charged particle beam inspection apparatus, and
the second region comprises a second portion of the first scan line in the field of view of the charged particle beam inspection apparatus, the second portion being different from the first portion.
   31. The method of clause 30, wherein the first region and the second region of the first the scan line correspond to a first multi-modality measurement sequence.
   32. The method of clause 31, further comprising:
measuring a third region of the sample with the charged particle beam inspection apparatus under the first signal acquisition modality to obtain a third signal profile; and
measuring a fourth region of the sample with the charged particle beam inspection apparatus under the second signal acquisition modality to obtain a fourth signal profile,
wherein generating the inspection image is further based on a synthesis of the third signal profile and the fourth signal profile.
   33. The method of clause 32, wherein:
the third region comprises a third portion of a second scan line in a field of view of the charged particle beam inspection apparatus, the second scan line being different from the first scan line, and
the fourth region comprises a fourth portion of the second scan line in the field of view of the charged particle beam inspection apparatus, the fourth portion being different from the third portion.
   34. The method of clause 33, wherein the third region and the fourth region of the second scan line correspond to a second multi-modality measurement sequence different from the first multi-modality measurement sequence.
   35. The method of clause 31, wherein the multi-modality measurement sequence does not correspond to a sequence of pattern features on the first region or the second region.
   36. The method of clause 31, wherein the multi-modality measurement sequence corresponds to a sequence of pattern features on the first region or the second region.
   37. The method of clause 36, wherein the multi-modality measurement sequence is based on prior information of the pattern features on the first region or the second region.
   38. The method of clause 36, further comprising:
updating the multi-modality measurement sequence during the measurement of the first region or the second region based on information obtained from the first region or the second region.
   39. The method of clause 24, wherein the second region corresponds to a sample feature within the first region.
   40. The method of clause 39, wherein the sample feature comprises an expected location of a pattern edge feature.
   41. The method of clause 24, wherein the first signal acquisition modality is configured to generate a larger interaction volume in the sample than the second signal acquisition modality.
   42. The method of clause 24, wherein the first signal acquisition modality is configured to achieve one of a higher signal acquisition speed, a higher signal to noise ratio, or a lower resolution than the second signal acquisition modality.
   43. The method of clause 24, wherein the inspection parameter of the charged particle beam apparatus comprises one of a beam current, landing energy, accelerating voltage, beam incidence angle, probe spot size, wafer orientation, beam scanning angle, field of view size, field of view shape, beam aperture setting, lens aberration value, focus value, and charged particle optics setting.
   44. The method of clause 24, wherein the optimization task comprises a loss function.
   45. The method of clause 24, wherein the optimization task comprises an inverse problem.
   46. The method of clause 45, wherein the optimization task comprises a deconvolution task.
   47. A charged particle beam apparatus, comprising:
a charged particle beam source configured to generate a beam of primary charged particles; a charged particle optical system configured to direct the beam of primary charged particles at a sample surface to inspect the sample surface;
a charged particle detector configured to detect charged particles returned from the sample surface; and a controller comprising one or more processors and configured to cause the charged particle beam apparatus to perform:
measuring a first region of a sample with a charged particle beam inspection apparatus under a first signal acquisition modality to obtain a first signal profile;
measuring a second region of the sample with the charged particle beam inspection apparatus under a second signal acquisition modality to obtain a second signal profile, the second signal acquisition modality being different from the first signal acquisition modality in an inspection parameter of the charged particle beam apparatus; and
generating, using an optimization task, an inspection image based on a synthesis of the first signal profile and the second signal profile.
   48. The charged particle beam apparatus of clause 47, wherein the first region and the second region are the same region.
   49. The charged particle beam apparatus of clause 47, wherein the first region is different from the second region.
   50. The charged particle beam apparatus of clause 49, wherein the first region and the second region do not overlap.
   51. The charged particle beam apparatus of clause 47, wherein the first region comprises a field of view of the charged particle beam inspection apparatus.
   52. The charged particle beam apparatus of clause 47, wherein:
the first region comprises a first scan line in a field of view of the charged particle beam inspection apparatus, and
the second region comprises a second scan line in the field of view of the charged particle beam inspection apparatus, the second scan line being different from the first scan line.
   53. The charged particle beam apparatus of clause 47, wherein:
the first region comprises a first portion of a first scan line in a field of view of the charged particle beam inspection apparatus, and
the second region comprises a second portion of the first scan line in the field of view of the charged particle beam inspection apparatus, the second portion being different from the first portion.
   54. The charged particle beam apparatus of clause 53, wherein the first region and the second region of the first the scan line correspond to a first multi-modality measurement sequence.
   55. The charged particle beam apparatus of clause 54, wherein the controller is configured to cause the charged particle beam apparatus to further perform:
measuring a third region of the sample with the charged particle beam inspection apparatus under the first signal acquisition modality to obtain a third signal profile; and
measuring a fourth region of the sample with the charged particle beam inspection apparatus under the second signal acquisition modality to obtain a fourth signal profile,
wherein generating the inspection image is further based on a synthesis of the third signal profile and the fourth signal profile.
   56. The charged particle beam apparatus of clause 55, wherein:
the third region comprises a third portion of a second scan line in a field of view of the charged particle beam inspection apparatus, the second scan line being different from the first scan line, and
the fourth region comprises a fourth portion of the second scan line in the field of view of the charged particle beam inspection apparatus, the fourth portion being different from the third portion.
   57. The charged particle beam apparatus of clause 56, wherein the third region and the fourth region of the second the scan line correspond to a second multi-modality measurement sequence different from the first multi-modality measurement sequence.
   58. The charged particle beam apparatus of clause 54, wherein the multi-modality measurement sequence does not correspond to a sequence of pattern features on the first region or the second region.
   59. The charged particle beam apparatus of clause 54, wherein the multi-modality measurement sequence corresponds to a sequence of pattern features on the first region or the second region.
   60. The charged particle beam apparatus of clause 59, wherein the multi-modality measurement sequence is based on prior information of the pattern features on the first region or the second region.
   61. The charged particle beam apparatus of clause 59, wherein the controller is configured to cause the charged particle beam apparatus to further perform:
updating the multi-modality measurement sequence during the measurement of the first region or the second region based on information obtained from the first region or the second region.
   62. The charged particle beam apparatus of clause 47, wherein the second region corresponds to a sample feature within the first region.
   63. The charged particle beam apparatus of clause 62, wherein the sample feature comprises an expected location of a pattern edge feature.
   64. The charged particle beam apparatus of clause 47, wherein the first signal acquisition modality is configured to generate a larger interaction volume in the sample than the second signal acquisition modality.
   65. The charged particle beam apparatus of clause 47, wherein the first signal acquisition modality is configured to achieve one of a higher signal acquisition speed, a higher signal to noise ratio, or a lower resolution than the second signal acquisition modality.
   66. The charged particle beam apparatus of clause 47, wherein the inspection parameter of the charged particle beam apparatus comprises one of a beam current, landing energy, accelerating voltage, beam incidence angle, probe spot size, wafer orientation, beam scanning angle, field of view size, field of view shape, beam aperture setting, lens aberration value, focus value, and charged particle optics setting.
   67. The charged particle beam apparatus of clause 47, wherein the optimization task comprises a loss function.
   68. The charged particle beam apparatus of clause 47, wherein the optimization task comprises an inverse problem.
   69. The charged particle beam apparatus of clause 68, wherein the optimization task comprises a deconvolution task.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes can be made without departing from the scope thereof. For example, a charged particle inspection system may be but one example of a charged particle beam system consistent with embodiments of the present disclosure.

1. A non-transitory computer-readable medium that stores a set of instructions that is executable by at least one processor of a charged particle beam apparatus to cause the charged particle beam apparatus to perform operations comprising:
measuring a first region of a sample under a first signal acquisition modality to obtain a first signal profile;
measuring a second region of the sample under a second signal acquisition modality to obtain a second signal profile, the second signal acquisition modality being different from the first signal acquisition modality in an inspection parameter of the charged particle beam apparatus; and
generating, using an optimization task, an inspection image based on a synthesis of the first signal profile and the second signal profile.

2. The non-transitory computer-readable medium of claim 1, wherein the first region and the second region are the same region.

3. The non-transitory computer-readable medium of claim 1, wherein the first region is different from the second region.

4. The non-transitory computer-readable medium of claim 3, wherein the first region and the second region do not overlap.

5. The non-transitory computer-readable medium of claim 1,
wherein the first region comprises a field of view of the charged particle beam apparatus.

6. The non-transitory computer-readable medium of claim 1,
wherein:
the first region comprises a first scan line in a field of view of the charged particle beam apparatus, and
the second region comprises a second scan line in the field of view of the charged particle beam apparatus, the second scan line being different from the first scan line.

7. The non-transitory computer-readable medium of claim 1, wherein:
the first region comprises a first portion of a first scan line in a field of view of the charged particle beam apparatus, and
the second region comprises a second portion of the first scan line in the field of view of the charged particle beam apparatus, the second portion being different from the first portion.

8. The non-transitory computer-readable medium of claim 7, wherein the first region and the second region of the first scan line correspond to a first multi-modality measurement sequence.

9. The non-transitory computer-readable medium of claim 8, wherein the operations further comprise:
measuring a third region of the sample with the charged particle beam apparatus under the first signal acquisition modality to obtain a third signal profile; and
measuring a fourth region of the sample with the charged particle beam apparatus under the second signal acquisition modality to obtain a fourth signal profile,
wherein generating the inspection image is further based on a synthesis of the third signal profile and the fourth signal profile.

10. The non-transitory computer-readable medium of claim 9, wherein:
the third region comprises a third portion of a second scan line in a field of view of the charged particle beam apparatus, the second scan line being different from the first scan line, and
the fourth region comprises a fourth portion of the second scan line in the field of view of the charged particle beam apparatus, the fourth portion being different from the third portion.

11. The non-transitory computer-readable medium of claim 10, wherein the third region and the fourth region of the second scan line correspond to a second multi-modality measurement sequence different from the first multi-modality measurement sequence.

12. The non-transitory computer-readable medium of claim 8, wherein the multi-modality measurement sequence does not correspond to a sequence of pattern features on the first region or the second region.

13. The non-transitory computer-readable medium of claim 8, wherein the multi-modality measurement sequence corresponds to a sequence of pattern features on the first region or the second region.

14. The non-transitory computer-readable medium of claim 13, wherein the multi-modality measurement sequence is based on prior information of the pattern features on the first region or the second region.

15. The non-transitory computer-readable medium of claim 13, wherein the operations further comprise:
updating the multi-modality measurement sequence during the measurement of the first region or the second region based on information obtained from the first region or the second region.

16. A charged particle beam apparatus, comprising:
a charged particle beam source configured to generate a beam of primary charged particles;
a charged particle optical system configured to direct the beam of primary charged particles at a sample surface to inspect the sample surface;
a charged particle detector configured to detect charged particles returned from the sample surface; and
a controller comprising one or more processors and configured to cause the charged particle beam apparatus to perform operations comprising:
measuring a first region of a sample under a first signal acquisition modality to obtain a first signal profile;
measuring a second region of the sample under a second signal acquisition modality to obtain a second signal profile, the second signal acquisition modality being different from the first signal acquisition modality in an inspection parameter of the charged particle beam apparatus; and
generating, using an optimization task, an inspection image based on a synthesis of the first signal profile and the second signal profile.

17. The charged particle beam apparatus of claim 16, wherein the first region and the second region are the same region.

18. The charged particle beam apparatus of claim 16, wherein the first region is different from the second region.

19. The charged particle beam apparatus of claim 18, wherein the first region and the second region do not overlap.

20. The charged particle beam apparatus of claim 16, wherein the first region comprises a field of view of the charged particle beam apparatus.
